(19) United States
(12) Patent Application Publication
(10) Pub. No.: US 2026/0313834 A1
(43) Pub. Date: Oct. 8, 2026

(54) TWO-STAGE LEVER SYSTEM FOR A SERVER TRAY IN A SERVER RACK

(71) Applicant: Dell Products L.P., Round Rock, TX (US)

(72) Inventors: Eduardo Escamilla, Round Rock, TX (US); James R. Utz, Georgetown, TX (US)

(21) Appl. No.: 19/173,164

(22) Filed: Apr. 8, 2025

(51) Int. Cl. H05K 7/20; H05K 7/14

(52) U.S. Cl. CPC H05K 7/20272; H05K 7/1489; H05K 7/1492; H05K 7/20772

(57) ABSTRACT

A computing environment, including: a server rack, including: a plurality of bays, wherein each bay includes a set of liquid connections; a server tray having a first end and a second end opposite to the first end, including: a server; a pair of brackets positioned at the second end, each bracket including liquid connectors; a pair of slider mechanisms extending between the first end and the second end, each slider mechanism coupled to one of the brackets; a pair of mounting brackets positioned at the first end, the mounting brackets coupled to the server; a pair of main levers positioned at the first end, each main lever coupled to one of the mounting brackets; a pair of auxiliary levers positioned at the first end, each auxiliary lever coupled to one of the slider mechanisms; wherein the server tray is positioned within a particular bay of the server rack.

### BACKGROUND

### Field of the Disclosure

The disclosure relates generally to a two-stage lever system for a server tray in a server rack.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Server trays are used to hold individual servers within a server rack, making it easier to slide servers in and out for maintenance or upgrades. They help in organizing and securing servers, ensuring they stay in place and are properly ventilated. Server racks, on the other hand, are larger structures designed to house multiple server trays, optimizing space and improving airflow in data centers. Together, server trays and racks enhance the efficiency, accessibility, and organization of server management.

### SUMMARY

Innovative aspects of the subject matter described in this specification may be embodied in a computing environment including a server rack, including: a plurality of bays; a bus bar extending across each of the plurality of bays; wherein each bay of the plurality of bays includes: a first set of liquid connections; a second set of liquid connections; a set of signal connections; a server tray having a first end and a second end opposite to the first end, and a first side and a second side opposite the first side positioned between the first end and the second end, the server tray including: a server; a first and a second bracket positioned at the second end, the first bracket including first liquid connectors and the second bracket including second liquid connectors; a set of signal connectors positioned at the second end; a bus bar clip positioned at the second end; a first and a second slider mechanism positioned at opposite sides of the first side and the second side and extending between the first end and the second end, the first slider mechanism coupled to the first bracket and the second slider mechanism coupled to the second bracket; a first and a second mounting bracket positioned at the first end, the first mounting bracket positioned at the first side and the second mounting bracket positioned at the second side, the mounting brackets coupled to the server; a first and a second main lever positioned at the first end, the first main lever coupled to the first mounting bracket and the second main lever coupled to the second mounting bracket; a first and a second auxiliary lever positioned at the first end, the first auxiliary lever coupled to the first slider mechanism and the second auxiliary lever coupled to the second slider mechanism; wherein the server tray is positioned within a particular bay of the server rack; wherein, when the main levers are in a main initial state and the auxiliary levers are in an auxiliary initial state, the main levers position the server tray such that: the set of signal connectors are spaced-apart from the set of the signal connections; the bus bar clip is spaced-apart from the bus bar; the first liquid connectors are spaced-apart from the first set of liquid connections a first distance; and the second liquid connectors are spaced-apart from the second set of liquid connections the first distance; wherein, when the main levers are in a main final state and the auxiliary levers are in the auxiliary initial state, the main levers position the server tray such that: the set of signal connectors are coupled with the set of signal connections; the bus bar clip is coupled with the bus bar; the first liquid connectors are spaced-apart from the first set of liquid connections a second distance less than the first distance; and the second liquid connectors are spaced-apart from the second set of liquid connections the second distance; wherein, when the main levers are in the main final state and the auxiliary levers are in an auxiliary final state, the auxiliary levers position the first and the second slider mechanisms such that: the first liquid connectors are coupled with the first set of liquid connections; and the second liquid connectors are coupled with the second set of liquid connections.

Other embodiments of these aspects include corresponding systems and apparatus.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of a server rack, including a plurality of server trays.

FIG. 3A illustrates a top down view of the server rack, with the server tray in a first position.

FIG. 3B illustrates a perspective view of the server tray in the first position.

FIG. 4A illustrates a top down view of the server rack, with the server tray in a second position.

FIG. 4B illustrates a perspective view of the server rack, with the server tray in the second position.

FIG. 5A illustrates a top down view of the server rack, with the server tray in a third position.

FIG. 5B illustrates a perspective view of the server rack, with the server tray in the third position.

FIG. 6A illustrates a top down view of the server rack, with the server tray in a fourth position.

FIG. 6B illustrates a perspective view of the server rack, with the server tray in the fourth position.

FIG. 7A illustrates a top down view of the server rack, with the server tray in a fifth position.

FIG. 7B illustrates a perspective view of the server rack, with the server tray in the fifth position.

FIG. 7C illustrates a perspective view of the server tray in the fifth position.

FIG. 8A illustrates a perspective view of a switch of the slider mechanism, in a first state.

FIG. 8B illustrates a perspective view of the switch of the slider mechanism, in a second state.

### DESCRIPTION OF PARTICULAR EMBODIMENT(S)

This disclosure discusses a two-stage lever system for a server tray in a server rack. In short, the invention involves using two-stage levers to distribute the forces of the liquid connections and signal/power connections. Initially, the server tray is levered into the server rack, establishing the signal and power connections. Subsequently, the liquid connections are made using their dedicated levers. This approach effectively divides the insertion forces into manageable portions, described further herein.

Specifically, this disclosure discusses a computing environment, including: a server rack, including: a plurality of bays, wherein each bay of the plurality of bays includes a set of liquid connections; a server tray having a first end and a second end opposite to the first end, the server tray including: a server; a pair of brackets positioned at the second end, each bracket including liquid connectors; a pair of slider mechanisms extending between the first end and the second end, each slider mechanism coupled to one of the brackets; a pair of mounting brackets positioned at the first end, the mounting brackets coupled to the server; a pair of main levers positioned at the first end, each main lever coupled to one of the mounting brackets; a pair of auxiliary levers positioned at the first end, each auxiliary lever coupled to one of the slider mechanisms; wherein the server tray is positioned within a particular bay of the server rack; wherein, when the main levers are in a main initial state, the main levers position the server tray such that: the liquid connectors are spaced-apart from the liquid connections a first distance; wherein, when the main levers are in a main final state, the main levers position the server tray such that: the liquid connectors are spaced-apart from the liquid connections a second distance less than the first distance; wherein, when the main levers are in the main final state and the auxiliary levers are in an auxiliary final state, the auxiliary levers position the slider mechanisms such that: the liquid connectors are coupled with the set of liquid connections.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

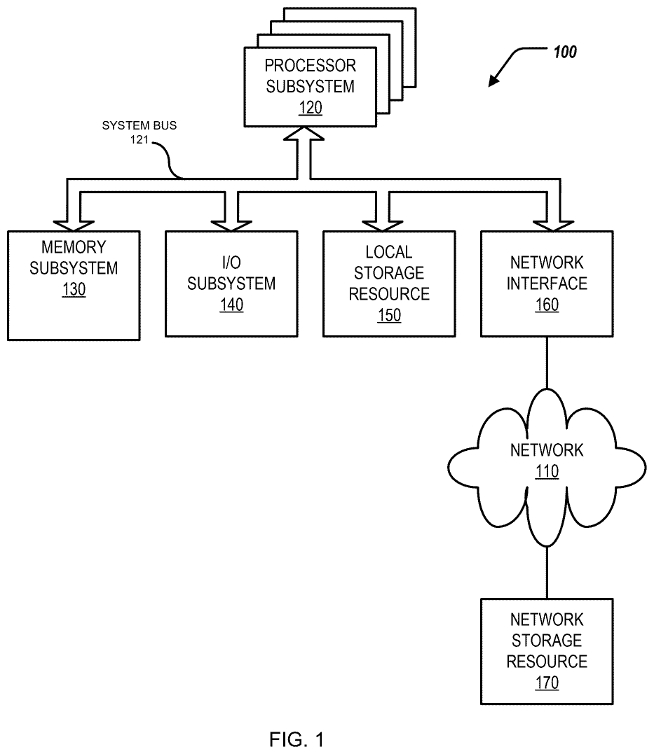

Particular embodiments are best understood by reference to FIGS. 1-8 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

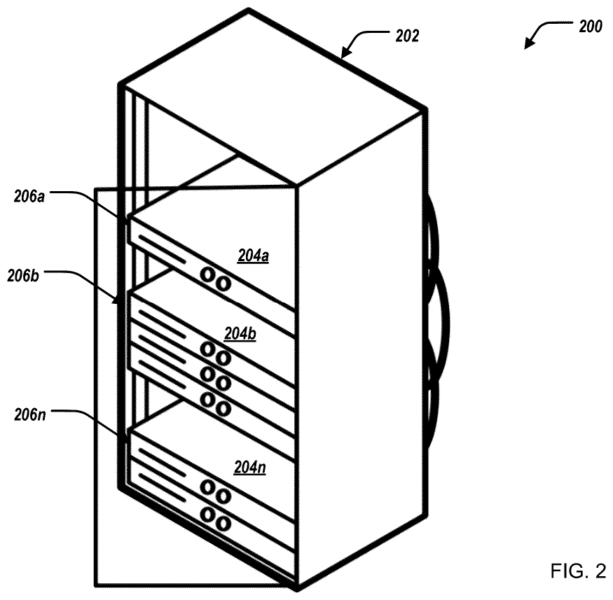

Turning to FIG. 2, FIG. 2 illustrates a block diagram of an environment 200 including a server rack 202. The server rack 202 can include bays 204a, 204b, . . . , 204n (collectively referred to as bays 204); and server trays 206a, 206b, . . . , 206n (collectively referred as server trays 206).

The server trays 206 can be (physically) coupled to respective bays 204.

In some examples, the server trays 206 are similar to, or include, the information handling system 100 of FIG. 1.

In short, the invention involves using two-stage levers to distribute the forces of the liquid connections and signal/power connections. Initially, the server tray is levered into the server rack, establishing the signal and power connections. Subsequently, the liquid connections are made using their dedicated levers. This approach effectively divides the insertion forces into manageable portions, described further herein.

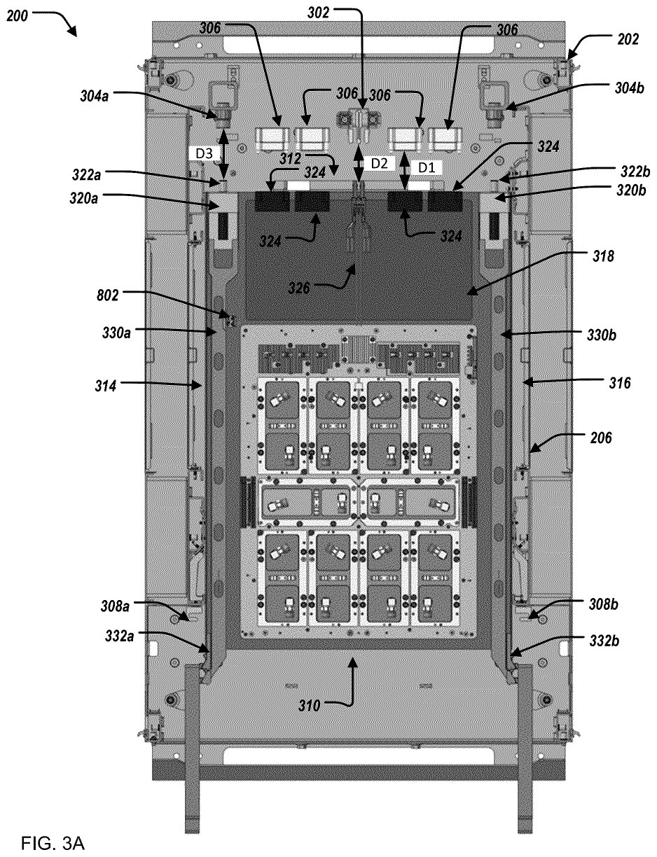

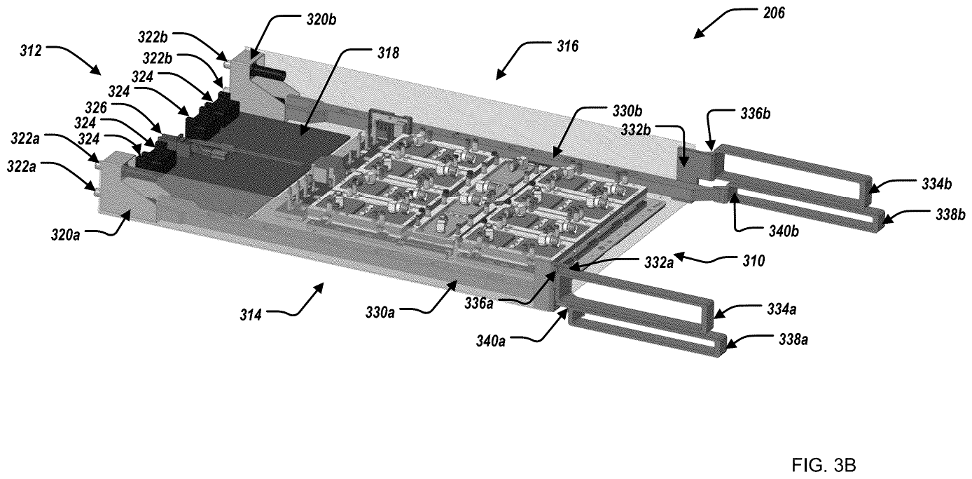

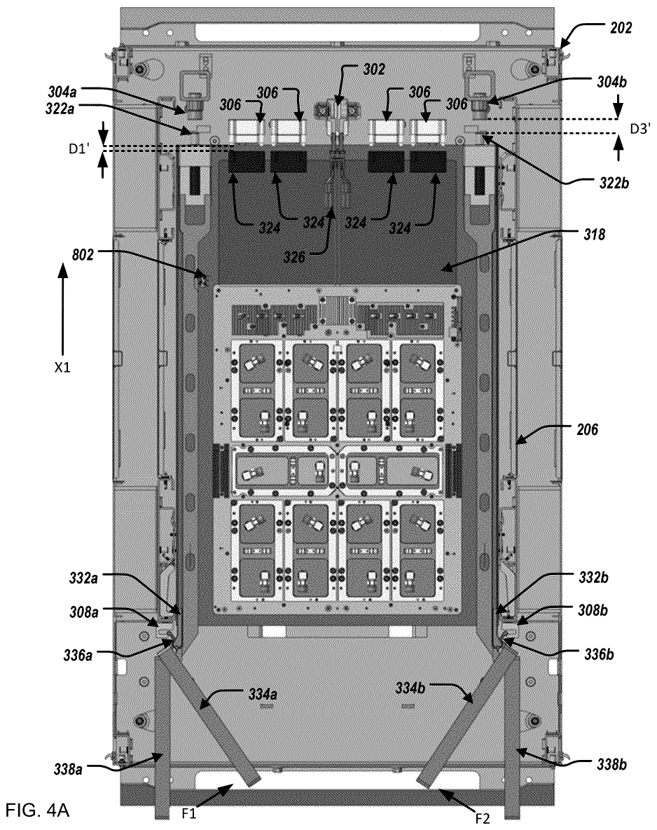

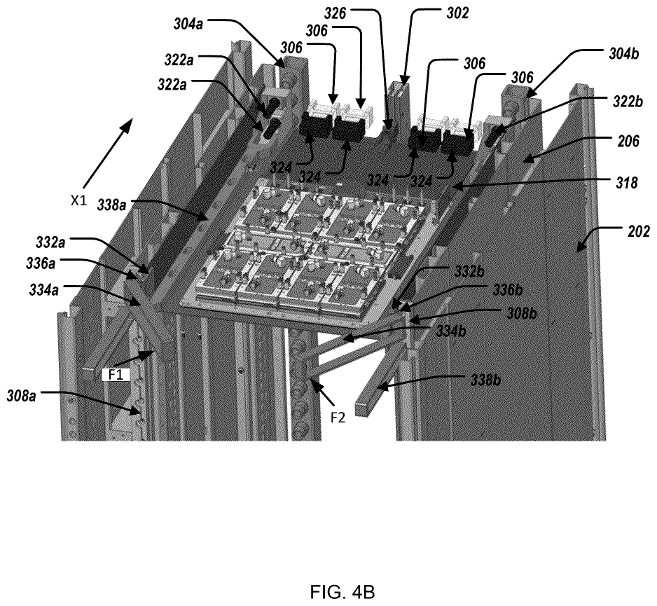

FIG. 3A illustrates a computing environment 200, and in particular, a top down view of the server rack 202, with the server tray 206 in a first position. FIG. 3B illustrates a perspective view of the server tray 206 in the first position. Referring to FIGS. 3A, 3B, specifically, the server tray 206 is positioned within a particular bay 204 of the server rack 202. The server rack 202 can include a bus bar 302 (shown more clearly in FIG. 4B). The bus bar 302 can extend across each of the bays 204. Each of the bays 204 can further include a first set of liquid connections 304a and a second set of liquid connections 304b (collectively referred to as liquid connections 304); however, each bay 204 can include any number of liquid connections. Each of the bays 204 can further include a set of signal connections 306; however, each bay 204 can include any number of signal connections. The server rack 202 can further include a first cam bar 308a and a second cam bar 308b (collectively referred to as cam bars 308).

The server tray 206 can include a first end 310 and a second end 312 opposite to the first end 310. The server tray 206 can further include a first side 314 and a second side 316 opposite to the first side 314. The first side 314 and the second side 316 are positioned between the first end 310 and the second end 312.

The server tray 206 can include a server 318. The server tray 206 can further include a first bracket 320a and a second bracket 320b (collectively referred to as brackets 320) positioned at the second end 312 of the server tray 206. The first bracket 320a is positioned along the first side 314, and includes first liquid connectors 322a. The second bracket 320b is positioned along the second side 316, and includes second liquid connectors 322b (the first liquid connectors 322a and the second liquid connectors 322b collectively referred to as liquid connectors 322). In some examples, the liquid connectors 322 are universal quick disconnect (UQD) liquid connectors.

The server tray 206 can further include a set of signal connectors 324 positioned at the second end 312 of the server tray 206. In some examples, the signal connectors are NVLINK signal connectors. The server tray 206 can further include a bus bar clip 326 positioned at the second end 312 of the server tray 206.

The server tray 206 can further include a first slider mechanism 330a and a second slider mechanism 330b (collectively referred to as slider mechanisms 330). The first slider mechanism 330a can be positioned proximate to the first side 314 of the server tray 206 and extend between the first end 310 and the second end 312 of the server tray 206. The first slider mechanism 330a is coupled to the first bracket 320a. The second slider mechanism 330b can be positioned proximate to the second side 316 of the server tray 206 and extend between the first end 310 and the second end 312 of the server tray 206. The second slider mechanism 330b is coupled to the second bracket 320b.

The server tray 206 can further include a first mounting bracket 332a and a second mounting bracket 332b (collectively referred to as mounting brackets 332). The first mounting bracket 332a is positioned at the first side 314 and coupled to the server 318. The second mounting bracket 332b is positioned at the second side 316 and coupled to the server 318.

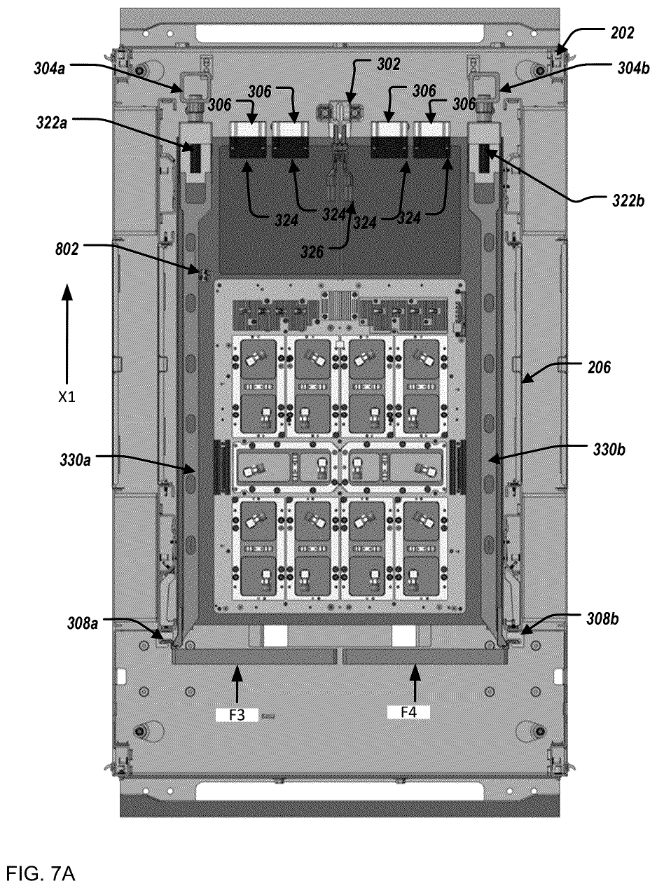

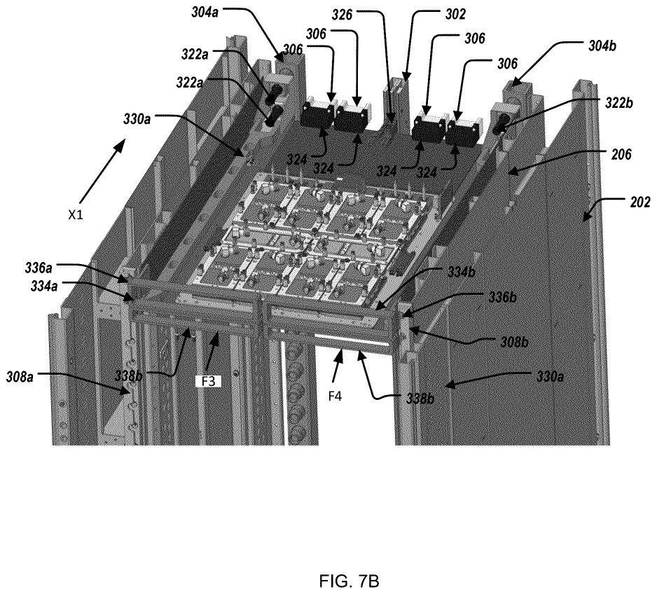

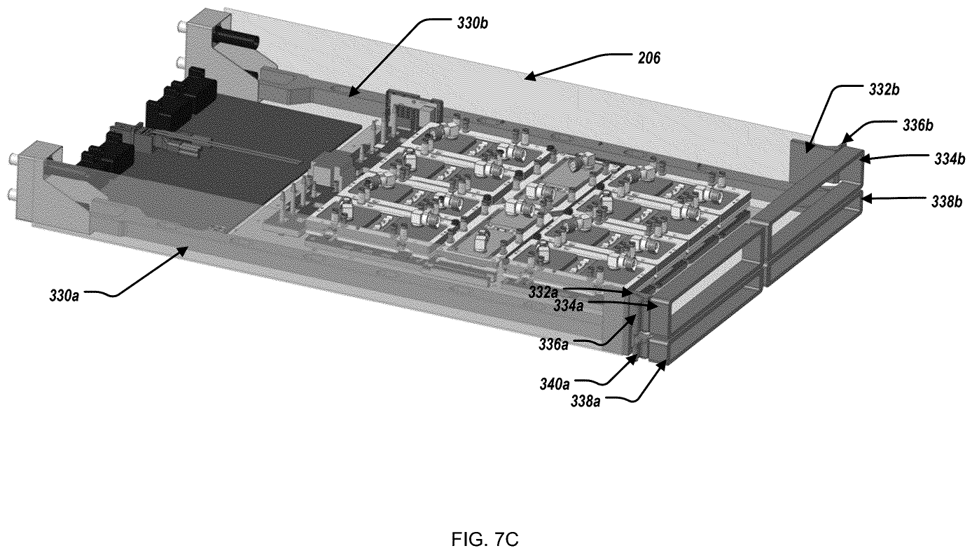

The server tray 206 can further include a first main lever 334a and a second main lever 334b (collectively referred to as main levers 334). The first main lever 334a is coupled to the first mounting bracket 332a and includes a first main lever cam pawl 336a (also shown in FIGS. 4A, 4B and 7C). The second main lever 334b is coupled to the second mounting bracket 332b and includes a second main lever cam pawl 336b (also shown in FIGS. 4A, 4B and 7C) (collectively referred to as main lever cam pawls 336).

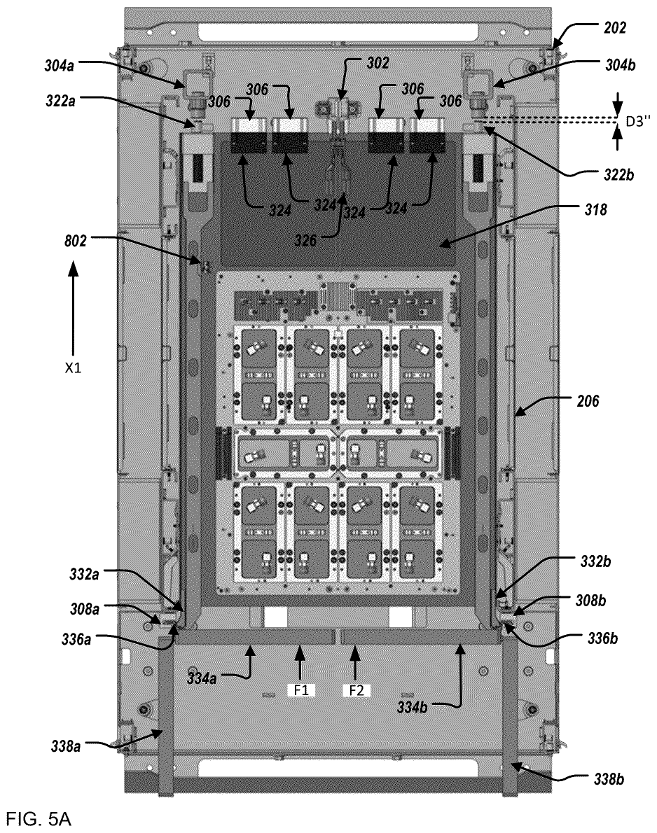

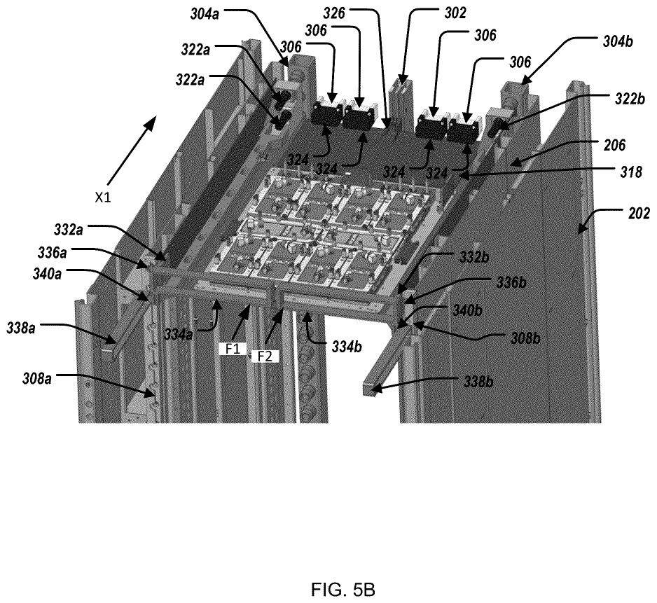

The server tray 206 can further include a first auxiliary lever 338a and a second auxiliary lever 338b (collectively referred to as auxiliary levers 338). The first auxiliary lever 338a is coupled to the first slider mechanism 330a and includes a first auxiliary lever cam pawl 340a (also shown in FIGS. 5B and 7C). The second auxiliary lever 338b is coupled to the second slider mechanism 330b and includes a second auxiliary lever cam pawl 340b (also shown in FIG. 5B) (collectively referred to as auxiliary lever cam pawls 340).

To that end, as mentioned herein, the FIGS. 3A, 3B illustrate the server tray 206 in a first position with respect to the server rack 202. Specifically, the main levers 334 are in a main initial state and the auxiliary levers 338 are in an auxiliary initial state to place the server tray 206 in the first position with respect to the server rack 202. That is, when the main levers 334 are in the main initial state and the auxiliary levers 338 are in the auxiliary initial state to place the server tray 206 in the first position with respect to the server rack 202, the main lever cam pawls 336 are disengaged from the cam bar 308 and the auxiliary lever cam pawls 340 are disengaged from the cam bar 308. Moreover, the set of signal connectors 324 of the server tray 206 are spaced-apart from the set of the signal connections 306 of the server rack 202 a distance D1; and the bus bar clip 326 of the server tray 206 is spaced-apart from the bus bar 302 of the server rack 202 a distance D2. That is, the signal connectors 324 are decoupled from the signal connections 306; and the bus bar clip 326 is decoupled from the bus bar 302. Furthermore, the liquid connectors 322 are spaced-apart from the liquid connections 304 a distance D3. That is, the liquid connectors 322 are decoupled from the liquid connections 304.

FIGS. 4A, 4B illustrate the server tray 206 in a second position with respect to the server rack 202. Specifically, the main levers 334 are in a main transition state and the auxiliary levers 338 are in the auxiliary initial state to place the server tray 206 in the second position with respect to the server rack 202. That is, when the main levers 334 are in the main transition state and the auxiliary levers 338 are in the auxiliary initial state to place the server tray 206 in the second position with respect to the server rack 202, the main lever cam pawls 336 are partially engaged with the cam bar 308 and the auxiliary lever cam pawls 340 are disengaged from the cam bar 308. Specifically, a force F1 can be applied to the first main lever 334a such that the first main lever cam pawl 336a partially engages with the cam bar 308a to partially rotate the first main lever 334a about the connection point between the first main lever cam pawl 336a and the first mounting bracket 332a, with the cam bar 308a providing a leverage point such that force F1 can be translated into movement of the server 318 along the direction X1. Similarly, a force F2 can be applied to the second main lever 334b such that the second main lever cam pawl 336b partially engages with the cam bar 308b to partially rotate the second main lever 334b about the connection point between the second main lever cam pawl 336b and the second mounting bracket 332b, with the cam bar 308b providing a leverage point such that force F2 can be translated into movement of the server 318 along the direction X1.

To that end, as a result of application of the forces F1 and F2 to translate the server 318 along the direction X1, the set of signal connectors 324 of the server tray 206 are spaced-apart from the set of the signal connections 306 of the server rack 202 a distance D1′, with the distance D1′ less than the distance D1. That is, the signal connectors 324 are decoupled from the signal connections 306. Further, as a result of application of the forces F1 and F2 to translate the server 318 along the direction X1, the bus bar clip 326 of the server tray 206 is partially engaged (or coupled) with the bus bar 302 of the server rack 202. Furthermore, as a result of application of the forces F1 and F2 to translate the server 318 along the direction X1, the liquid connectors 322 are spaced-apart from the liquid connections 304 a distance D3′, with the distance D3′ less than the distance D3. That is, the liquid connectors 322 are decoupled from the liquid connections 304.

FIGS. 5A, 5B illustrate the server tray 206 in a third position with respect to the server rack 202. Specifically, the main levers 334 are in a main final state and the auxiliary levers 338 are in the auxiliary initial state to place the server tray 206 in the third position with respect to the server rack 202. That is, when the main levers 334 are in the main final state and the auxiliary levers 338 are in the auxiliary initial state to place the server tray 206 in the third position with respect to the server rack 202, the main lever cam pawls 336 are fully engaged with the cam bar 308 and the auxiliary lever cam pawls 340 are disengaged from the cam bar 308. Specifically, the force F1 is applied to the first main lever 334a such that the first main lever cam pawl 336a fully engages with the cam bar 308a to fully rotate the first main lever 334a about the connection point between the first main lever cam pawl 336a and the first mounting bracket 332a, with the cam bar 308a providing a leverage point such that the force F1 can be translated into movement of the server 318 along the direction X1. Similarly, the force F2 is applied to the second main lever 334b such that the second main lever cam pawl 336b fully engages with the cam bar 308b to rotate the second main lever 334b about the connection point between the second main lever cam pawl 336b and the second mounting bracket 332b, with the cam bar 308b providing a leverage point such that force F2 can be translated into movement of the server 318 along the direction X1.

To that end, as a result of application of the forces F1 and F2 to translate the server 318 along the direction X1, the set of signal connectors 324 of the server tray 206 are fully engaged (or coupled) with the set of the signal connections 306 of the server rack 202. Further, as a result of application of the forces F1 and F2 to translate the server 318 along the direction X1, the bus bar clip 326 of the server tray 206 is fully engaged (or coupled) with the bus bar 302 of the server rack 202. Furthermore, as a result of application of the forces F1 and F2 to translate the server 318 along the direction X1, the liquid connectors 322 are spaced-apart from the liquid connections 304 a distance D3″, with the distance D3″ less than the distance D3′. That is, the liquid connectors 322 are decoupled from the liquid connections 304.

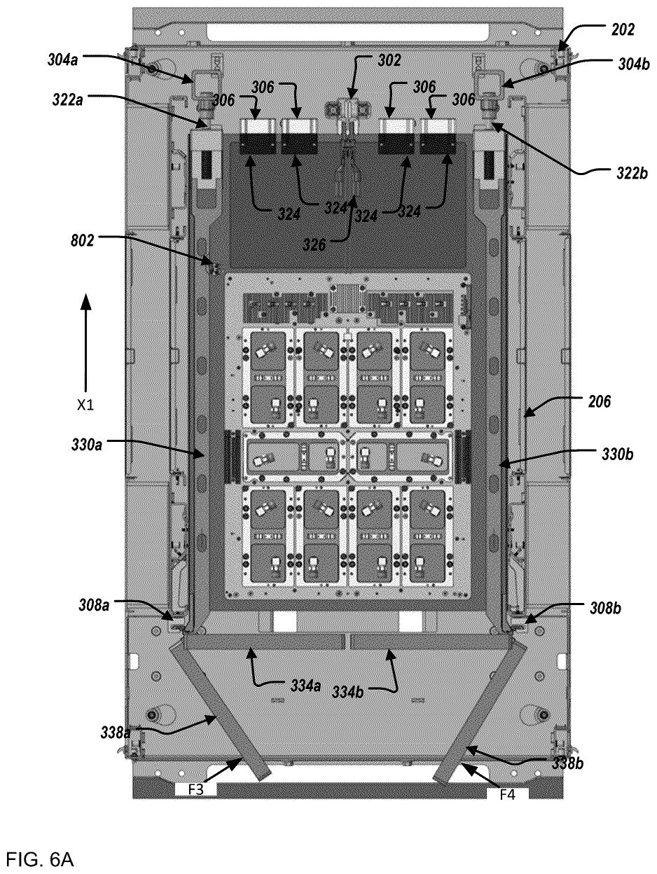

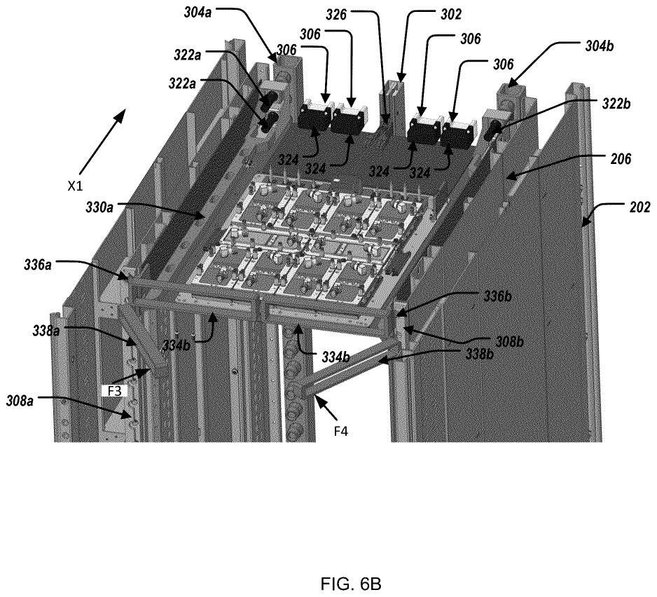

FIGS. 6A, 6B illustrate the server tray 206 in a fourth position with respect to the server rack 202. Specifically, the main levers 334 are in the main final state and the auxiliary levers 338 are in an auxiliary transition state to place the server tray 206 in the fourth position with respect to the server rack 202. That is, when the main levers 334 are in the main final state and the auxiliary levers 338 are in the auxiliary transition state to place the server tray 206 in the fourth position with respect to the server rack 202, the main lever cam pawls 336 are fully engaged with the cam bar 308 and the auxiliary lever cam pawls 340 are partially engaged with the cam bar 308. Specifically, the force F3 is applied to the first auxiliary lever 338a such that the first auxiliary lever cam pawl 340a (shown in FIGS. 5B, 7C) partially engages with the cam bar 308a to partially rotate the first auxiliary lever 338a about the connection point between the first auxiliary lever cam pawl 340a (shown in FIGS. 5B, 7C) and the first slider mechanism 330a, with the cam bar 308a providing a leverage point such that the force F3 can be translated into movement of the first slider mechanism 330a along the direction X1. Similarly, the force F4 is applied to the second auxiliary lever 338b such that the second auxiliary lever cam pawl 340b (shown in FIG. 5B) partially engages with the cam bar 308b to partially rotate the second auxiliary lever 338b about the connection point between the second auxiliary lever cam pawl 340b (shown in FIG. 5B) and the second slider mechanism 330b, with the cam bar 308b providing a leverage point such that the force F4 can be translated into movement of the second slider mechanism 330b along the direction X1.

To that end, as a result of application of the forces F3 and F4 to translate the slider mechanisms 330 along the direction X1, the liquid connectors 322 are partially engaged (or coupled) with the liquid connections 304. Furthermore, the set of signal connectors 324 of the server tray 206 remain fully engaged (or coupled) with the set of the signal connections 306 of the server rack 202; and the bus bar clip 326 of the server tray 206 remains fully engaged (or coupled) with the bus bar 302 of the server rack 202.

FIGS. 7A, 7B, 7C illustrate the server tray 206 in a fifth position with respect to the server rack 202. Specifically, the main levers 334 are in the main final state and the auxiliary levers 338 are in an auxiliary final state to place the server tray 206 in the fifth position with respect to the server rack 202. That is, when the main levers 334 are in the main final state and the auxiliary levers 338 are in the auxiliary final state to place the server tray 206 in the fifth position with respect to the server rack 202, the main lever cam pawls 336 are fully engaged with the cam bar 308 and the auxiliary lever cam pawls 340 are fully engaged with the cam bar 308. Specifically, the force F3 is applied to the first auxiliary lever 338a such that the first auxiliary lever cam pawl 340a (shown in FIGS. 5B, 7C) fully engages with the cam bar 308a to fully rotate the first auxiliary lever 338a about the connection point between the first auxiliary lever cam pawl 340a (shown in FIGS. 5B, 7C) and the first slider mechanism 330a, with the cam bar 308a providing a leverage point such that the force F3 can be translated into movement of the first slider mechanism 330a along the direction X1. Similarly, the force F4 is applied to the second auxiliary lever 338b such that the second auxiliary lever cam pawl 340b (shown in FIGS. 5B, 7C) fully engages with the cam bar 308b to fully rotate the second auxiliary lever 338b about the connection point between the second auxiliary lever cam pawl 340b (shown in FIG. 5B) and the second slider mechanism 330b, with the cam bar 308b providing a leverage point such that the force F4 can be translated into movement of the second slider mechanism 330b along the direction X1.

To that end, as a result of application of the forces F3 and F4 to translate the slider mechanisms 330 along the direction X1, the liquid connectors 322 are fully engaged (or coupled) with the liquid connections 304. Furthermore, the set of signal connectors 324 of the server tray 206 remain fully engaged (or coupled) with the set of the signal connections 306 of the server rack 202; and the bus bar clip 326 of the server tray 206 remains fully engaged (or coupled) with the bus bar 302 of the server rack 202.

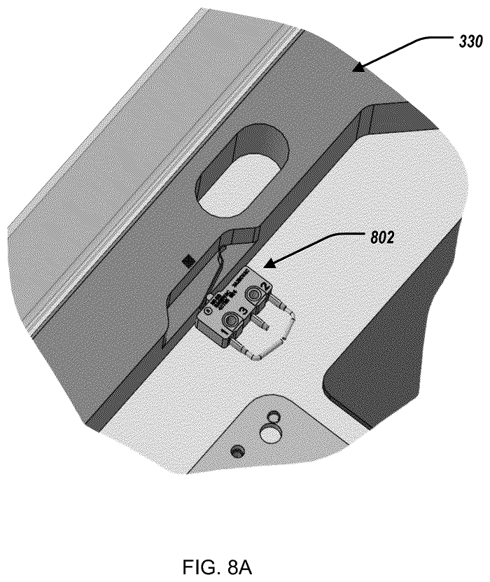

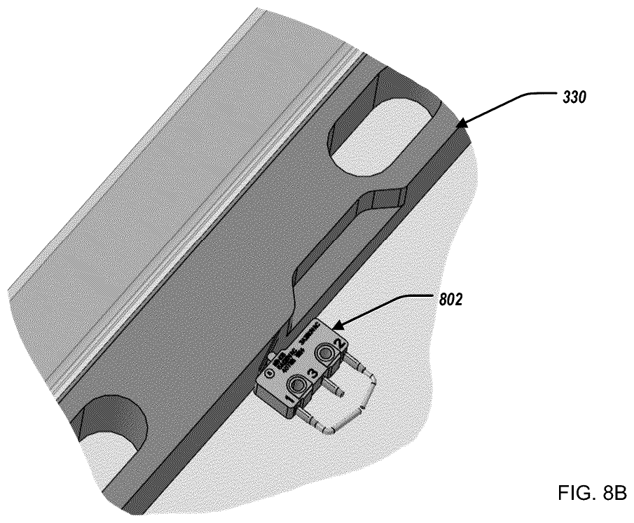

FIG. 8A illustrates a perspective view of a switch 802 of the slider mechanism 330, in a first state. In short, the switch can indicate when the liquid connectors 322 are fully engaged or disengaged from the liquid connections 304. In the first state, as shown in FIG. 8A, the auxiliary levers 338 are in the auxiliary initial state, and the auxiliary levers 338 position the slider mechanism 330 such that the switch 802 is in the first state (as shown in FIG. 5A). The first state of the switch 802 can indicate that the liquid connectors 322 are not coupled with the liquid connections 304. That is, the slider mechanism 330 does not engage the switch 802 such that the switch is in the first state when the auxiliary levers 338 are in the auxiliary initial state. This can prevent providing power to the server 318 prematurely (e.g., via the bus bar 302 and the bus bar clip 326) before the liquid connectors 322 are fully engaged with the liquid connections 304, thus limiting damage to the server 318.

FIG. 8B illustrates a perspective view of a switch 802 of the slider mechanism 330, in a second state. In the second state, as shown in FIG. 8B, the auxiliary levers 338 are in the auxiliary final state, and the auxiliary levers 338 position the slider mechanism 330 such that the switch 802 is in the second state (as shown in FIG. 7A). The second state of the switch 802 can indicate that the liquid connectors 322 are coupled with the liquid connections 304. That is, the slider mechanism 330 engages the switch 802 such that the switch is in the second state when the auxiliary levers 338 are in the auxiliary final state. This can allow providing power to the server 318 (e.g., via the bus bar 302 and the bus bar clip 326) after the liquid connectors 322 are fully engaged with the liquid connections 304.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A computing environment, including:
a server rack, including:
a plurality of bays, wherein each bay of the plurality of bays includes a set of liquid connections;
a server tray having a first end and a second end opposite to the first end, the server tray including:
a server;
a pair of brackets positioned at the second end, each bracket including liquid connectors;
a pair of slider mechanisms extending between the first end and the second end, each slider mechanism coupled to one of the brackets;
a pair of mounting brackets positioned at the first end, the mounting brackets coupled to the server;
a pair of main levers positioned at the first end, each main lever coupled to one of the mounting brackets;
a pair of auxiliary levers positioned at the first end, each auxiliary lever coupled to one of the slider mechanisms;
wherein the server tray is positioned within a particular bay of the server rack;
wherein, when the main levers are in a main initial state, the main levers position the server tray such that:
the liquid connectors are spaced-apart from the liquid connections a first distance;
wherein, when the main levers are in a main final state, the main levers position the server tray such that:
the liquid connectors are spaced-apart from the liquid connections a second distance less than the first distance;
wherein, when the main levers are in the main final state and the auxiliary levers are in an auxiliary final state, the auxiliary levers position the slider mechanisms such that:
the liquid connectors are coupled with the set of liquid connections.

2. The computing environment of claim 1, wherein at least one of the slider mechanisms includes a switch, wherein when the auxiliary levers are in the auxiliary final state, the auxiliary levers position the slider mechanisms such that the switch is in a second state indicating that the liquid connectors are coupled with the set of liquid connections.

3. The computing environment of claim 2, wherein when the auxiliary levers are in an auxiliary initial state, the auxiliary levers position the slider mechanisms such that the switch is in a first state indicating that the liquid connectors are not coupled with the set of liquid connections.

4. The computing environment of claim 1, wherein
the server rack further includes:
a bus bar extending across each of the plurality of bays,
wherein each bay of the plurality of bays further includes a set of signal connections;
the server further includes:
a set of signal connectors positioned at the second end; and
a bus bar clip positioned at the second end.

5. The computing environment of claim 4, wherein, when the main levers are in the main initial state, the main levers position the server tray such that:
the set of signal connectors are spaced-apart from the set of the signal connections; and
the bus bar clip is spaced-apart from the bus bar.

6. The computing environment of claim 5, wherein, when the main levers are in the main final state, the main levers position the server tray such that:
the set of signal connectors are coupled with the set of signal connections; and
the bus bar clip is coupled with the bus bar.

7. The computing environment of claim 6,
wherein the server has a first side and a second side opposite to the first side and positioned between the first end and the second end;
wherein the pair of slider mechanisms are positioned at opposite sides of the first and the second side; and
wherein the pair of mounting brackets are positioned at opposite sides of the first and the second side.

8. The computing environment of claim 7,
wherein, when the main levers are in the main initial state and the auxiliary levers are in an auxiliary initial state, the main levers position the server tray such that:
the set of signal connectors are spaced-apart from the set of the signal connections;
the bus bar clip is spaced-apart from the bus bar; and
the liquid connectors are spaced-apart from the liquid connections the first distance.

9. The computing environment of claim 8,
wherein, when the main levers are in the main final state and the auxiliary levers are in the auxiliary initial state, the main levers position the server tray such that:
the set of signal connectors are coupled with the set of signal connections;
the bus bar clip is coupled with the bus bar; and
the liquid connectors are spaced-apart from the liquid connections a second distance less than the first distance.

10. A computing environment, including:
a server rack, including:
a plurality of bays;
a bus bar extending across each of the plurality of bays;
wherein each bay of the plurality of bays includes:
a set of liquid connections;
a set of signal connections;
a server tray having a first end and a second end opposite to the first end, the server tray including:
a server;
a pair of brackets positioned at the second end, each bracket including liquid connectors;
a set of signal connectors positioned at the second end;
a bus bar clip positioned at the second end;
a pair of slider mechanisms extending between the first end and the second end, each slider mechanism coupled to one of the brackets;
a pair of mounting brackets positioned at the first end, the mounting brackets coupled to the server;
a pair of main levers positioned at the first end, each main lever coupled to one of the mounting brackets;
a pair of auxiliary levers positioned at the first end, each auxiliary lever coupled to one of the slider mechanisms;
wherein the server tray is positioned within a particular bay of the server rack;
wherein, when the main lever is in a main initial state, the main levers position the server tray such that:
the set of signal connectors are spaced-apart from the set of the signal connections;
the bus bar clip is spaced-apart from the bus bar;
the liquid connectors are spaced-apart from the liquid connections a first distance;
wherein, when the main lever is in a main final state, the main levers position the server tray such that:
the set of signal connectors are coupled with the set of signal connections;
the bus bar clip is coupled with the bus bar;
the liquid connectors are spaced-apart from the liquid connections a second distance less than the first distance;
wherein, when the main levers are in the main final state and the auxiliary levers are in an auxiliary final state, the auxiliary levers position the slider mechanisms such that:
the liquid connectors are coupled with the set of liquid connections.

11. The computing environment of claim 10, wherein at least one of the slider mechanisms includes a switch, wherein when the auxiliary levers are in the auxiliary final state, the auxiliary levers position the slider mechanisms such that the switch is in a second state indicating that the liquid connectors are coupled with the set of liquid connections.

12. The computing environment of claim 11, wherein when the auxiliary levers are in an auxiliary initial state, the auxiliary levers position the slider mechanisms such that the switch is in a first state indicating that the liquid connectors are not coupled with the set of liquid connections.

13. The computing environment of claim 12,
wherein the server has a first side and a second side opposite to the first side and positioned between the first end and the second end;
wherein the pair of slider mechanisms are positioned at opposite sides of the first and the second side; and
wherein the pair of mounting brackets are positioned at opposite sides of the first and the second side.

14. The computing environment of claim 13,
wherein, when the main levers are in the main initial state and the auxiliary levers are in the auxiliary initial state, the main levers position the server tray such that:
the set of signal connectors are spaced-apart from the set of the signal connections;
the bus bar clip is spaced-apart from the bus bar; and
the liquid connectors are spaced-apart from the liquid connections the first distance.

15. The computing environment of claim 14,
wherein, when the main levers are in the main final state and the auxiliary levers are in the auxiliary initial state, the main levers position the server tray such that:
the set of signal connectors are coupled with the set of signal connections;
the bus bar clip is coupled with the bus bar; and
the liquid connectors are spaced-apart from the liquid connections a second distance less than the first distance.

16. A computing environment, including:
a server rack, including:
a plurality of bays;
a bus bar extending across each of the plurality of bays;
wherein each bay of the plurality of bays includes:
a first set of liquid connections;
a second set of liquid connections;
a set of signal connections;
a server tray having a first end and a second end opposite to the first end, and a first side and a second side opposite the first side positioned between the first end and the second end, the server tray including:
a server;
a first and a second bracket positioned at the second end, the first bracket including first liquid connectors and the second bracket including second liquid connectors;
a set of signal connectors positioned at the second end;
a bus bar clip positioned at the second end;
a first and a second slider mechanism positioned at opposite sides of the first side and the second side and extending between the first end and the second end, the first slider mechanism coupled to the first bracket and the second slider mechanism coupled to the second bracket;
a first and a second mounting bracket positioned at the first end, the first mounting bracket positioned at the first side and the second mounting bracket positioned at the second side, the mounting brackets coupled to the server;
a first and a second main lever positioned at the first end, the first main lever coupled to the first mounting bracket and the second main lever coupled to the second mounting bracket;
a first and a second auxiliary lever positioned at the first end, the first auxiliary lever coupled to the first slider mechanism and the second auxiliary lever coupled to the second slider mechanism;
wherein the server tray is positioned within a particular bay of the server rack;
wherein, when the main levers are in a main initial state and the auxiliary levers are in an auxiliary initial state, the main levers position the server tray such that:
the set of signal connectors are spaced-apart from the set of the signal connections;
the bus bar clip is spaced-apart from the bus bar;
the first liquid connectors are spaced-apart from the first set of liquid connections a first distance; and
the second liquid connectors are spaced-apart from the second set of liquid connections the first distance;
wherein, when the main levers are in a main final state and the auxiliary levers are in the auxiliary initial state, the main levers position the server tray such that:
the set of signal connectors are coupled with the set of signal connections;
the bus bar clip is coupled with the bus bar;
the first liquid connectors are spaced-apart from the first set of liquid connections a second distance less than the first distance; and
the second liquid connectors are spaced-apart from the second set of liquid connections the second distance;
wherein, when the main levers are in the main final state and the auxiliary levers are in an auxiliary final state, the auxiliary levers position the first and the second slider mechanisms such that:
the first liquid connectors are coupled with the first set of liquid connections; and
the second liquid connectors are coupled with the second set of liquid connections.

17. The computing environment of claim 16, wherein at least one of the slider mechanisms includes a switch, wherein when the auxiliary levers are in the auxiliary final state, the auxiliary levers position the slider mechanisms such that the switch is in a second state indicating that the first liquid connectors are coupled with the set of liquid connections and the second liquid connectors are coupled with the second set of liquid connections.

18. The computing environment of claim 17, wherein when the auxiliary levers are in the auxiliary initial state, the auxiliary levers position the slider mechanisms such that the switch is in a first state indicating that the first liquid connectors are not coupled with the first set of liquid connections and the second liquid connectors are not coupled with the second set of liquid connections.
